(19) United States
(12) Patent Application Publication
(10) Pub. No.: US 2013/0192885 A1
(43) Pub. Date: Aug. 1, 2013

(54) METHOD OF FORMING SOLDER RESIST LAYER AND PRINTED CIRCUIT BOARD COMPRISING SOLDER RESIST LAYER

(71) Applicant: SAMSUNG TECHWIN CO., LTD., Changwon-city (KR)

(72) Inventors: Sang-Min LEE, Changwon-city (KR); Soon-Chul KWON, Changwon-city (KR)

(73) Assignee: SAMSUNG TECHWIN CO., LTD., Changwon-city (KR)

(21) Appl. No.: 13/756,942

(22) Filed: Feb. 1, 2013

(30) Foreign Application Priority Data
Feb. 1, 2012 (KR) 10-2012-0011208

(51) Int. Cl. H05K 3/00; H05K 1/03; H05K 1/02

(52) U.S. Cl. CPC H05K 3/0058; H05K 1/02; H05K 1/0353
USPC 174/258; 156/307.1; 216/20

(57) ABSTRACT

Provided are a method of forming a solder resist layer on a printed circuit board (PCB) and a PCB comprising the solder resist layer. The method includes: preparing a PCB of which at least one surface has a circuit layer formed thereon, bonding an insulation layer, including a material having a non-photosensitive characteristic, in a half-cured state on the circuit layer, forming a solder resist layer patterned by selectively removing the insulation layer, and curing the insulation layer.

### CROSS-REFERENCE TO RELATED PATENT APPLICATION

This application claims priority from Korean Patent Application No. 10-2012-0011208, filed on Feb. 3, 2012, in the Korean Intellectual Property Office, the disclosure of which is incorporated herein in its entirety by reference.

### BACKGROUND

1. Field

Methods and apparatuses consistent with exemplary embodiments relate to forming a solder resist layer and a printed circuit board (PCB) comprising the solder resist layer

2. Description of the Related Art

A solder resist layer formed on a PCB is a coating covering an interconnection circuit and preventing solder around a land, on which a component is mounted, from becoming wet so that an unintended connection from soldering does not occur between mounted components. Since the solder resist layer shields a portion around the land in this way, it is also called a solder mask.

By forming the solder resist layer on the PCB, a short-circuit, lamination, corrosion or contamination of the PCB may be prevented, and the circuit may be protected from external impacts, moisture or chemical substances.

This method of forming the solder resist layer will be briefly described with reference to drawings. FIGS. 1A-1C illustrate sequential cross-sectional views of a PCB which show a method of forming a solder resist layer according to a related art screen printing method. FIG. 2A-2C illustrate sequential cross-sectional views of a PCB which shows a method of forming a solder resist layer according to a related art photoresist method.

According to the screen printing method disclosed in Korean Patent Publication No. 10-2005-0036979 and Korean Patent Application No. 10-2006-0069810 and the like, as shown in FIGS. 1A-1C, a patterned solder resist layer 100-1 is formed as shown in FIG. 1C by disposing a solder resist (SR) ink 2 onto a substrate using a rubber bar 3 and a plate 1 as a mask. However, there is a limitation in applying the foregoing method of directly printing a solder resist layer to PCBs which have a fine pitch.

According to demands for fine pitch PCBs, in the photoresist method disclosed in Korean patent publication No. 10-2010-0042018 as shown in FIGS. 2A-2C, a solder resist layer 100-1 is formed by a photoresist method of forming a patterned solder resist through photo solder resist (PSR) exposure using a PSR mask 5 and a PSR developing process (see FIG. 2B) after coating a photosensitive PSR ink 4 on all the surfaces of a substrate.

When the solder resist layer 100-1 is patterned according to this photoresist method, the PSR ink 4 causes the patterned solder resist to be formed through the PSR exposure and development process. Therefore the PSR ink 4 is made to include a photosensitive material.

When formed using the PSR ink 4 including the photosensitive material, the solder resist layer 100-1 may be formed on a fine-pitch PCB. However, in this case, the formed solder resist layer has different properties from a resin which is the original material of the PCB, causing a difference in Coefficient of Thermal Expansion (CTE). Due to this CTE difference, warpage occurs in assembling the PCB, and cracking and delamination occur in a high temperature. In addition, a high water absorption ratio causes ion migration due to water absorption in an actual environment in which a product having the PCB is used, which prevents a JEDEC level 1 or 2 reliability required for a package board to be achieved.

Recently a method of applying SR ink and realizing a patterned solder resist layer using a laser has been studied. However, there are limitations of high cost for a laser source and low productivity from a process employing a laser. Therefore, it is highly necessary that a solder resist layer having high productivity and reliability can be formed at a low cost.

### SUMMARY

One or more exemplary embodiments provide a method of forming a solder resist layer and a PCB comprising the solder resist layer having high reliability.

According to an aspect of an exemplary embodiment, there is provided a method of forming a solder resist layer including: preparing a PCB of which at least one surface has a circuit layer formed thereon, bonding an insulation layer, including a material having a non-photosensitive characteristic, in a half-cured state on the circuit layer, forming a solder resist layer patterned by selectively removing the insulation layer, and curing the insulation layer.

The material of the insulation layer may be identical to a material constituting a core layer of the PCB.

The insulation layer may comprise at least one of epoxy resin, polyimide resin, Bismaleimide Triazine (BT) resin and Teflon resin.

The insulation layer may be a prepreg.

In the forming the solder resist layer, the insulation layer may be selectively removed by disposing a film on the insulation layer and patterning the solder resist using the film as a mask.

The bonding the insulation layer may include: tack-bonding the insulation layer and the metal thin film on at least one surface of the circuit layer; and patterning a metal thin film by selectively etching the metal thin film.

The method may further include removing the metal thin film before the curing the insulation layer or after the curing the insulation layer.

The removing the metal thin film may include etching and removing the metal thin film in its entirety.

According to an aspect of another exemplary embodiment, there is provided a PCB including the solder resist layer formed according to the above-described method.

### BRIEF DESCRIPTION OF THE DRAWINGS

The above and other aspects will become more apparent by describing in detail exemplary embodiments thereof with reference to the attached drawings, in which:

FIGS. 1A-1C illustrate sequential cross-sectional views of a PCB which show a method of forming a solder resist layer according to a related art screen printing method;

FIGS. 2A-2C illustrate sequential cross-sectional views of a PCB which show a method of forming a solder resist layer according to a related art photoresist method;

FIG. 3 is a cross-sectional view of a PCB comprising a solder resist layer according to an exemplary embodiment;

FIGS. 4A and 4B are flowcharts illustrating a method of forming a solder resist layer according to an exemplary embodiment; and

FIGS. 5A-5E illustrate sequential cross-sectional views of a PCB which show a method of forming a solder resist layer according to an exemplary embodiment.

### DETAILED DESCRIPTION OF THE EXEMPLARY EMBODIMENTS

Hereinafter, one or more exemplary embodiments will be described in detail with reference to accompanying drawings. Also, in drawings, same reference numerals denote same elements to avoid repetition.

In the drawings, thicknesses of layers and regions are exaggerated for clarity.

As used herein, the term “and/or” includes any and all combinations of one or more of the associated listed items. Expressions such as “at least one of,” when preceding a list of elements, modify the entire list of elements and do not modify the individual elements of the list.

Solder Resist Layer

Here a solder resist layer formed by a method according to an exemplary embodiment will be described with reference to the drawings.

FIG. 3 is a cross-sectional view of a PCB comprising a solder resist layer according to an exemplary embodiment.

As shown in FIG. 3, a PCB comprising a solder resist layer according to an exemplary embodiment includes a circuit layer 11 on at least one surface of the PCB and a solder resist layer 100 on the circuit layer 11.

Here, the solder resist layer 100 according to the exemplary embodiment basically includes a thermosetting resin, and a material of the solder resist layer 100 has non-photosensitive property inactive to light.

Namely, reliability is secured between the circuit layer 11, and core layer 12 and solder resist layer 100 by excluding a photosensitive material.

Properties of a copper clad laminate (CCL) resin including a thermosetting resin and the PSR ink may be represented in Table 1 below.

TABLE 1

| | | CCL | | | PSR |
|---|---|---|---|---|---|
| | | A company | B company | C company | D company |
| Maker | | product | product | product | product |
| CTE | X | 13/16 | 14 | 12.7 | 50/140 |
| | Y | 8/12 | 14 | 13.1 | — |
| | Z | — | 55/220 | 24.1 | — |
| Tg | ° C. | 214(DMA) | 210(DMA) | 165(TMA) | 105(TMA) |
| | | | 185(DMA) | | |
| Water | % | 0.35 | — | 0.36 | 1.3 |
| Absorption | | | | | |
| Peel | kg/cm | 0.7(18 μm) | 0.9(12 μm) | 0.87(12 μm) | — |
| Strength | | | 1.0(18 μm) | | |
| Dielectric | — | 5(@MHz) | 4.6(@MHz) | 4.85(@MHz) | — |
| Constant | | | 4.3(@GHz) | 4.53(@GHz) | |
| Dissipation | — | 0.01(@MHz) | 0.007(@MHz) | 0.0085(@MHz) | — |
| Factor | | | 0.0015(@GHz) | 0.0104(@GHz) | |
| Thermal | — | 288° C./10 s × 5 | — | 121° C./2.1 atm/4 hr | — |
| Resistivity | | | | | |
| Young's | GPa | 13 | 24/26 | — | 2.7 |
| Modulus | | | | | |

Comparing properties of the CCL resin and a PSR ink, numbers indicating properties differ for each manufacturer or each model. However, comparing CTE (ppm/° C.), a value of the PSR ink is greater than a value of the CCL resin, and thus, dimension change in the PSR ink is also greater than in the CCL according to temperature change. Comparing glass transition temperature Tg (° C.), the PSR ink has a lower glass transition temperature than the CCL resin, and thus, the PSR ink becomes more flexible than the CCL at a low temperature. Comparing the water absorption ratio (%), the PSR ink has greater water absorption ratio than the CCL resin, and thus, the PSR ink is superior to the CCL resin in water absorption.

As described above, a reason why the property of the PSR ink differs from the property of the CCL resin is because the PSR ink includes a photosensitive material for exposure and development in order to perform patterning on the solder resist layer using the PSR ink.

In contrast, a material of the solder resist layer 100 according to the exemplary embodiment has a characteristic of non-photosensitivity inactive to light. In addition, the material forming the solder resist layer 100 includes a thermosetting resin which is identical or similar to a material of the core layer 12 of the PCB, thereby securing high reliability, increasing productivity by simplifying processes and/or equipment, and reducing a manufacturing cost.

At this time, the material of the solder resist layer 100 may be identical to a material of the core layer 12 of the PCB. When the material of the solder resist layer 100 is identical to a material constituting the core layer 12 of the PCB and layers having identical properties are laminated, effects of warpage prevention in an assembling process, and prevention of crack and delamination at a high temperature can be improved.

The material of the solder resist layer 100 may be specifically a thermosetting resin used in the core layer 12 of the PCB such as epoxy resin, polyimide resin, Bismaleimide Triazine (BT) resin or Teflon resin, or a prepreg in which the thermosetting resin is immersed with paper, a glass fiber, a nonwoven glass or the like in order to improve mechanical strength or resistivity to temperature.

The solder resist layer 100 may be formed to be laminated by heating and/or pressurization, and thus, a surface of the solder resist layer formed in this way is smooth.

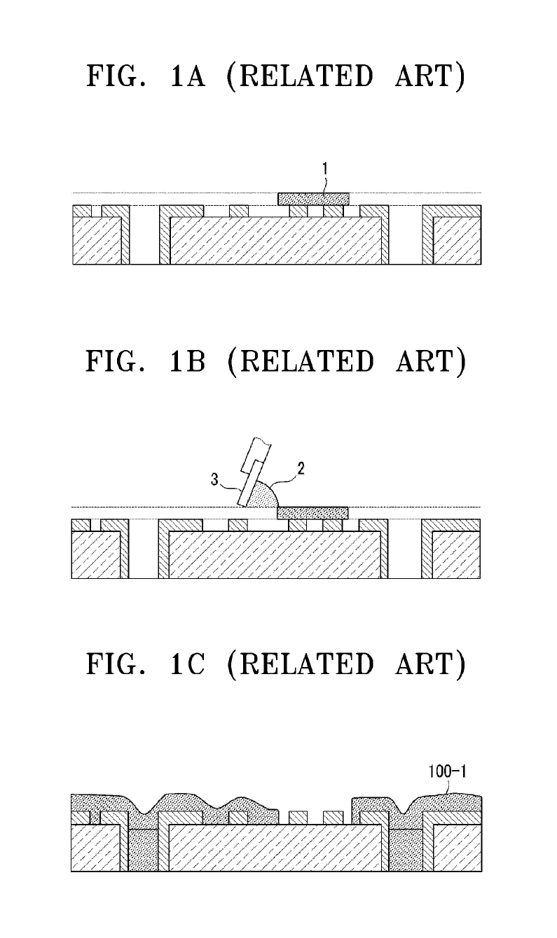

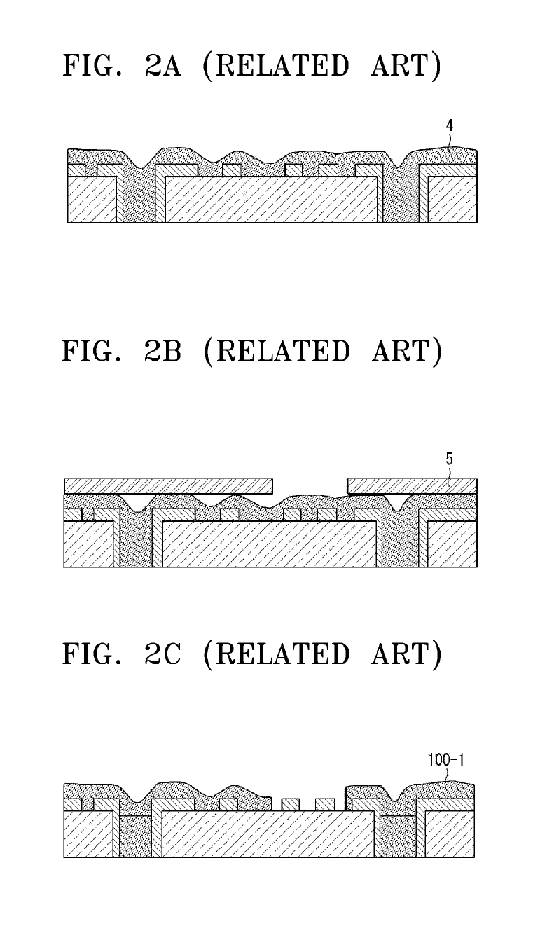

A surface of the solder resist layer 100-1 as shown in FIGS. 1A-1C and 2A-2C is not smooth but uneven, which is different from a surface of the solder resist layer 100 according to the exemplary embodiment. This causes a void from a space formed in the solder resist layer when a semiconductor package is assembled on the PCB.

Namely, as shown in FIG. 3, the surface of the solder resist layer 100 according to the exemplary embodiment is formed smoothly, which is different from the surface of the solder resist layer formed by using the PSR ink in the related art. Therefore, there is no concern of a space being caused by the solder resist layer and little concern of a void being caused in the solder resist layer in a case of assembling the semiconductor package.

Hereinafter, a method of forming the solder resist layer 100 will be described in detail.

Method of Forming a Solder Resist Layer

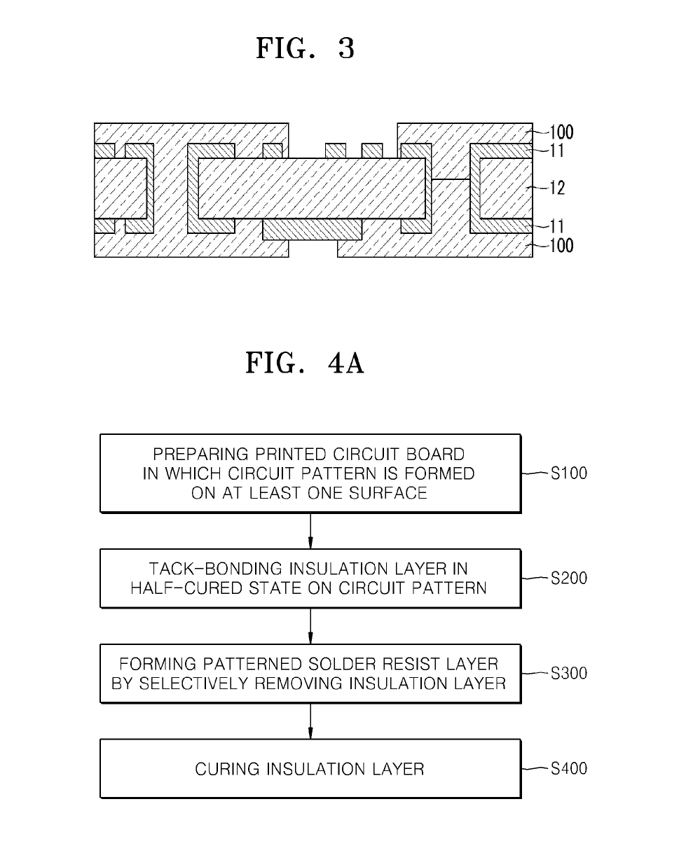

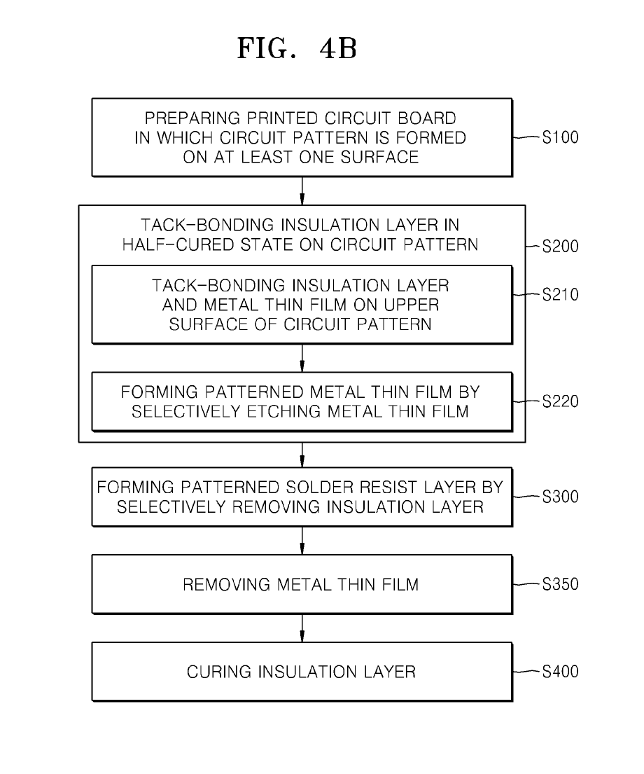

FIGS. 4A and 4B are flowcharts illustrating a method of forming a solder resist layer according to an exemplary embodiment.

As shown in FIG. 4A, a method of forming a solder resist layer according to an exemplary embodiment includes preparing a PCB of which at least one surface has a circuit layer 11 formed thereon (S100), bonding a half-cured insulation layer on the circuit layer 11 (S200), removing selectively the insulation layer to form a patterned solder resist layer (S300) and curing the insulation layer (S400). In operatoin S200, the bonding the half-cured insulation layer may be performed by tack-bonding.

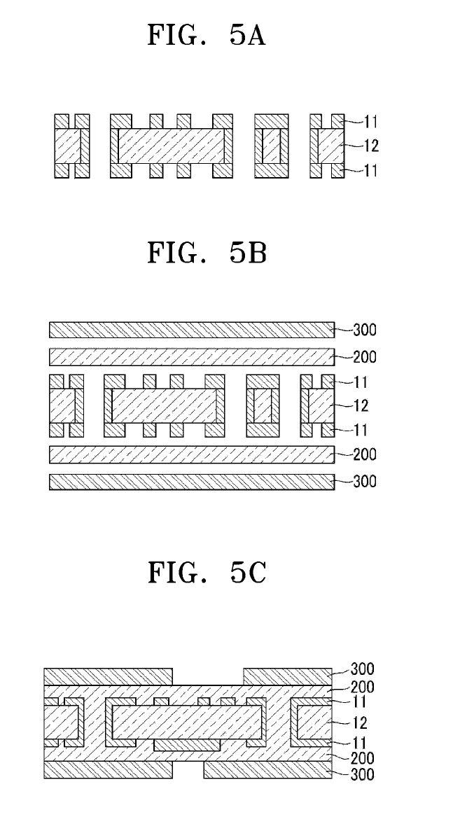

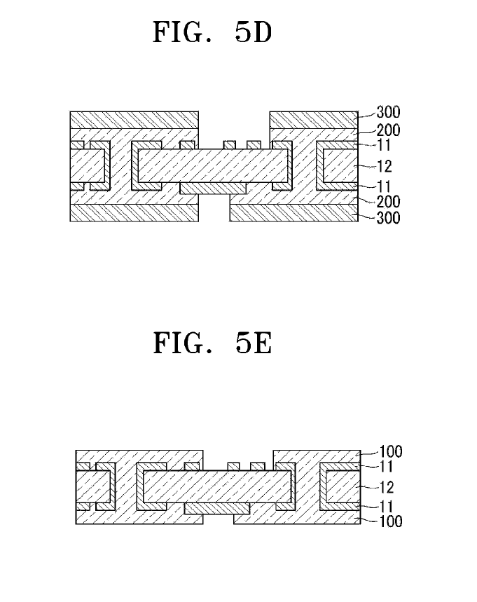

Hereinafter, each operation of the method of forming a solder resist layer according to an exemplary embodiment will be described with reference to FIGS. 5A-5E illustrating sequential cross-sectional views of the PCB.

First, the PCB of which at least one surface has the circuit layer 11 formed thereon is prepared (S100) (see FIG. 5A).

Namely, the PCB on which the solder resist layer is to be formed is prepared in order to protect a surface of the PCB and prevent an inadvertent connection by soldering performed in part mounting.

Then, the insulation layer 200 in a half-cured state is tack-bonded on the circuit layer 11 (S200) (see FIG. 5B).

The insulation layer 200 is a layer to be formed as the solder resist layer patterned by resin-etching and is formed by laminating insulation layers including a thermosetting resin excluding non-photosensitive material inactive to light or a resin identical to a material of a core layer 12 of the PCB.

The material of the insulation layer 200 may include, as described above, one or more of epoxy resin, polyimide resin, BT resin and Teflon resin or may be a prepeg made by immersing the same in paper, a glass fiber, a nonwoven glass or the like.

Here, a state of the laminated insulation layer 200 is a half-cured state but not a fully cured state of a polymer resin. Namely, it is a state of low molecular resin in which the resin is not fully melted and fluidity remains in an intermediate process of a thermosetting resin reaction.

In addition, the tack-bonding indicates a process of forming and/or bonding the insulation layer 200 in a half-cured state prior to a fully polymerized state on the circuit layer 11 formed on the PCB, namely, a process of forming and/or bonding the insulation layer 200 by applying high pressure at a low temperature before the insulation layer 200 is fully cured, which depends on a curing condition of the curing agent included in the insulation layer 200.

In other words, in a typical hot press process, forming and curing are performed simultaneously by compressing the insulation layer with high pressure at a high temperature for a long time in one process. However, in the exemplary embodiment, the forming and curing processes are separated from each other, the insulation layer is tack-bonded and formed before the insulation layer is fully cured to be polymerized. After some necessary processes, the formed insulation layer is fully cured to be polymerized.

After the tack-bonding of the insulation layer 200 on the circuit layer 11, the formed insulation layer is selectively removed to form the insulation layer 200 having a pattern as the solder resist (S300) (see FIG. 5D).

When patterned to be the solder resist, the insulation layer 200 may be resin-etched in a half-cured state.

When the insulation layer 200 is fully cured to be polymerized and patterned by resin-etching, an efficiency of resin-etching may deteriorate due to increase of chemical resistance of a polymerized thermosetting resin.

An etchant for selectively removing to pattern the insulation layer 200 is for resin-etching. The etchant may be exemplified as one of basically including a strong acid, but detailed description thereof is beyond the scope of the exemplary embodiment and will be omitted here.

In operation S400, the insulation layer is cured to form the patterned solder resist layer 100 (see FIG. 5E).

Forming of the solder resist layer 100 is completed by heating and curing the insulation layer 200 in a patterned and half-cured state through a post-curing process.

### Embodiments

Hereinafter a method of forming a solder resist layer according to the exemplary embodiment will be described in detail with reference to FIGS. 4A-4B and 5A-5E. Repeated description related to the foregoing method of forming the solder resist layer will be omitted.

FIGS. 5A-5E illustrate sequential cross-sectional views of a PCB which show a method of forming a solder resist layer according to an exemplary embodiment.

As shown in FIG. 5A, a PCB of which at least one surface has a circuit layer 11 formed thereon is prepared (S100).

A pre-processing process may be performed to form a solder resist layer on the at least one surface before an insulation layer 200 in a half-cured state is tack-bonded on the circuit layer 11.

The pre-processing process may include an oxidation process such as black oxide or brown oxide, or pre-processing etching for increasing adhesion to the circuit layer 11 of the PCB before laminating the insulation layer 200.

Then, a tack-bonding of the insulation layer 200 in a half-cured state on the circuit layer 11 may be performed, as shown in FIG. 5B, through tack-bonding the insulation layer 200 and a metal thin film 300 on an upper surface of the circuit layer 11 (S210), and selectively etching the metal thin film 300 to pattern the metal thin film 300 (S220).

When the insulation layer 200 is tack-bonded to be adhered on the upper surface of the circuit layer 11, the insulation layer 200 and the metal thin film 300 may be simultaneously tack-bonded. At this time, the insulation layer 200 may be tack-bonded in the half-cured state, so that the resin etching for the insulation layer 200 can be performed efficiently.

In the above, the insulation layer 200 is tack-bonded on the circuit layer 11 formed on one surface of the PCB. When the circuit layers 11 are formed on two surfaces of the PCB, the insulation layers 200 are also tack-bonded on the two circuit layers 11.

In operation S220, the metal thin film 300 is selectively etched in correspondence to a desired pattern of the solder resist layer 100. Accordingly, the metal thin film 300 operates as a mask to resin-etch the insulation layer 200.

In order to form the patterned metal thin film 300, a photosensitive film is laminated on the metal thin film 300, and then, exposure, development, etching and photolithography of stripping the photosensitive film may be performed in order.

In operation 300, as shown in FIG. 5D, the insulation layer 200 is patterned by resin-etching and selectively removing the insulation layer 200 with the patterned metal thin film 300 adopted as a mask.

As described above, it is preferable, but not necessary, to resin-etch the insulation layer 200 in a half-cured state before the insulation layer 200 is fully cured and the chemical resistance increases.

When the circuit layer 11 and insulation layer 200 are formed on two sides of the PCB, the two sides may be resin-etched simultaneously.

According to the exemplary embodiment, productivity can be improved by forming two insulation layers 200 simultaneously on two sides of the PCB wherein the two insulation layers 200 are patterned by resin-etching the two sides of the PCB simultaneously. Namely, in order to form the solder resist layer in the related art, a PSR ink is applied to one side of the PCB and provisional-dried, the PSR ink is applied to another side of the PCB and provisional-dried, exposure and development are performed on each side to pattern the solder resist layer, and then, post-curing and PSR ink curing processes are performed. However, in the method of forming a solder resist layer according to the exemplary embodiment, time-consuming processes such as the PSR ink application and provisional-dry processes of the solder resist layer forming method in the related art can be omitted.

In operation S400, as shown in FIG. 5E, the patterned solder resist layer 100 is formed by curing to polymerize the insulation layer 200.

As described above, forming and curing the insulation layer 200 according to exemplary embodiment are not performed simultaneously in one process, but performed separately by forming the insulation layer 200 with high pressure at a low temperature in the tack-bonding process in operation 200, selectively removing the insulation layer 200, performing necessary processes, heating and curing the insulation layer 200.

Here, the heating process is performed by post-curing for fully curing the insulation layer 200. The post-curing is identical to the curing of the PSR ink in the related art. Therefore, detailed description thereof is omitted. However there is a difference in a material to be cured between the post-curing according to the exemplary embodiment and the PSR curing in the related art, so curing conditions for the temperature may be differed.

In addition, the method of forming the solder resist layer 100 may further include removing (S350) the patterned metal thin film 300. As shown in FIG. 5E, the removing of the patterned thin film 300 may be performed before the curing of the insulation layer 200 and after the resin-etching, or after the curing (S400) of the insulation layer 200.

Here, the removing the metal thin film 300 may be performed by etching the entire metal thin film 300, and in this case the two-sided metal thin films 300 are removed simultaneously.

In the removing the metal thin film 300, various methods other than the etching may also be adopted.

According to the exemplary embodiment, a solder resist layer having high reliability can be formed at a low cost even in a fine pitch PCB.

In the PCB comprising the solder resist layer according to the exemplary embodiment, when the solder resist layer includes a thermosetting resin but is formed of a non-photosensitive material or a same material as one of a core layer of the PCB, a CTE difference between the core layer of the PCB and the solder resist layer is none or small. Therefore, warpage may not occur in assembling the PCB, and also, a crack and delamination may not occur at a high temperature.

A PCB comprising a solder resist layer according to the exemplary embodiment has so small a water absorption ratio that ion migration due to water absorption may not occur. Therefore, reliability on the PCB can be secured.

A method of forming a photo resist according to the exemplary embodiment does not need a separate piece of equipment and a process for an SR ink or a PSR ink application to form the solder resist layer as in the related art, thereby reducing the number of pieces of equipment and processes.

In a method of forming a solder resist layer according to the exemplary embodiment, in order to form the solder resist layer, simultaneous patterning on the two surfaces of the PCB is possible by resin-etching instead of processes for an SR ink or a PSR ink application and a provisional-dry for each surface of the PCB as in the related art, thereby improving productivity.

While the exemplary embodiment have been particularly shown and described above, it will be understood by those of ordinary skill in the art that various changes in form and details may be made therein without departing from the spirit and scope of the present inventive concept as defined by the following claims.

What is claimed is:

1. A method of forming a solder resist layer comprising:
preparing a printed circuit board (PCB) of which at least one surface has a circuit layer formed thereon;
bonding an insulation layer, comprising a material having a non-photosensitive characteristic, in a half-cured state on the circuit layer;
forming a solder resist layer patterned by selectively removing the insulation layer; and
curing the insulation layer.

2. The method according to claim 1, wherein the material of the insulation layer is identical to a material constituting a core layer of the PCB.

3. The method according to claim 2, wherein the material of the insulation layer comprises at least one of epoxy resin, polyimide resin, Bismaleimide Triazine (BT) resin and Teflon resin.

4. The method according to claim 1, wherein the material of the insulation layer comprises at least one of epoxy resin, polyimide resin, Bismaleimide Triazine (BT) resin and Teflon resin.

5. The method according to claim 1, wherein the insulation layer is a prepreg.

6. The method according to claim 1, wherein in the forming the solder resist layer, the insulation layer is selectively removed by disposing a film on the insulation layer and patterning the solder resist using the film as a mask.

7. The method according to claim 6, where the bonding the insulation layer comprises:
tack-bonding the insulation layer and the metal thin film on at least one surface of the circuit layer; and
patterning a metal thin film by selectively etching the metal thin film.

8. The method according to claim 7, further comprising:
removing the metal thin film before the curing the insulation layer or after the curing the insulation layer.

9. The method according to claim 8, wherein the removing the metal thin film comprises etching and removing the metal thin film in its entirety.

10. The method according to claim 1, wherein the preparing the PCB comprises preparing a PCB of which an upper surface and a lower surface have respective circuits formed thereon,
wherein the bonding the insulation layer comprises bonding respective insulation layers on the upper surface and the lower surface of the PCB,
wherein the forming the solder resist layer comprises forming respective solder resist layers by selectively removing the respective insulation layers, and
wherein the curing the insulation layer comprises curing the respective insulation layers.

11. The method according to claim 10, wherein the respective solder resist layers are formed simultaneously by selectively removing the respective insulation layers simultaneously.

12. A printed circuit board (PCB) comprising the solder resist layer formed by the method according to claim 1.

13. The PCB of claim 12, wherein the material of the insulation layer is identical to a material constituting a core layer of the PCB.

14. The PCB of claim 13, wherein the material of the insulation layer comprises at least one of epoxy resin, polyimide resin, Bismaleimide Triazine (BT) resin and Teflon resin.

15. The PCB of claim 12, wherein the material of the insulation layer comprises at least one of epoxy resin, polyimide resin, Bismaleimide Triazine (BT) resin and Teflon resin.

16. A printed circuit board (PCB) comprising:
a substrate;
a circuit layer formed on at least one surface of the substrate; and
a solder resist layer formed on the circuit layer,
wherein the solder resist layer comprises a material having a non-photosensitive characteristic.

17. The PCB of claim 16, wherein the material of the solder resist layer is identical to a material constituting a core layer of the PCB.

18. The PCB of claim 17, wherein the material of the solder resist layer comprises at least one of epoxy resin, polyimide resin, Bismaleimide Triazine (BT) resin and Teflon resin.

19. The PCB of claim 16, wherein the material of the solder resist layer comprises at least one of epoxy resin, polyimide resin, Bismaleimide Triazine (BT) resin and Teflon resin.
